(19) United States
(12) Patent Application Publication
(10) Pub. No.: US 2007/0076377 A1
(43) Pub. Date: Apr. 5, 2007

(54) Bi-Polar Thermal Managment

(75) Inventor: Matteo B. Gravina, Laredo, TX (US)

Correspondence Address: MATTEO B. GRAVINA, 5835 LONGORIA LOOP, LAREDO, TX, 78041, US

(73) Assignee: Matteo B. Gravina, Laredo, TX (US)

(21) Appl. No.: 11/163,027

(22) Filed: Oct. 3, 2005

(51) Int. Cl. H05K 7/20

(52) U.S. Cl. 361/710

(57) ABSTRACT

The invention is a thermal management device for extracting heat from a semiconductor device. The proper extraction of heat generated by semiconductors in general central processor unit is supported by a bi-level design. Heat generated by a working microprocessor is produced from the actual semiconductor architecture onto its housing. The bi-level thermal management system improves heat extraction by managing heat at two levels. Heat is received and transfer by the bottom surface and the upper surface of the central processor. The invention receives heat from the two surfaces transfer thermal energy to upper levels of the heat sink. Generally, heat extraction is aided further by fanning at top of the heat sink.

Electronics and Computers are now not a new concept. Decades ago when electronics technology was at the leading edge computers did not play a major role. Electrical mechanical processes were the norm in everyday automated processing of goods and services. With the invention of the transistor and years later, the microprocessor proved a milestone in their respective times. The basic operations the computers of the time were small and did not required complex work. During the eighties decade the integration of very high large-scale integrated circuitry (VLSI) and the coming nineties decade with the internet prove a bonanza. At last, everything was coming together and consumers began to buy computers a steady pace. The eventual number of integrated densities of semiconductors started to create problems. Because of the density factor semiconductors and demanding work loads the number crunching of central processing units are heating up. Complex machinery that is computers are began to slow and sometimes stomping computer activity. The problems were the heating up of microprocessors. The increase high demands place on central processors lethargic their abilities.

At the core of computers are the microprocessors. These complex processing units execute almost every interaction by a computer system and integrated accessories. As their abilities grew in capacity, the new problems of heat accumulation lessen their capacities. As processing increase so did heating up. Today with complex software and demanding hardware the microprocessor easily heat up and have to come with heat sinks. The advent of these problems was contemplated with the new use of heat sinks.

During the middle nineties basic heat sink solutions were introduce. Metallic corrugated metal blocs with fins were the norm. With higher heat densities the integration of fans decreases the heat accumulation. Also today as in previous years designs in the heat sinks are being introduced. Other means of expediting heat from microprocessors are the use of liquid cooling solutions. All together, these means of cooling processors are proven effective. Nevertheless, they all fall short as a rule of thumb, microprocessors capacities grow every year.

### SUMMARY

The main objective of the present invention is to reduce heat accumulation on an integrated circuit. Thermal maintenance at the microprocessor level still remains a problem in means of cooling. Thermal heat expedition by innovative designs and transference of heat energy at the integrated circuit level still plagues IT departments, as well as the average consumers. Whether creating a new fan, heat sink, or venting the transference of air flow inside a computer, the heat associated with microprocessors still is a problem. To directly contemplate the ever-changing logarithmic growth of central processing unit capacities and heat accumulation the usual becomes obsolete at a certain point.

This new innovative design confronts this ever growing problem of heat accumulation and expedition of heat accumulation on a microprocessor. The means of dissipating heat from a source by attacking it by opposite sides is not new. On the other hand making this possible at the microprocessor level is. The innovative design is new means of bi-level thermal management. Bi-level thermal management of heat energy is the transference of heat from opposite sides. Heat energy accumulated in this case is from electron flow on circuits inside a package.

An advantage of bi-level thermal management on a package circuit is a more thorough sweep of heat energy and expediting it. By attacking the heat from opposite side the invention advantageously gathers heat from the bottom side of the microprocessor which is equal in surface area to the top side. This is clear advantage heat sinks as the bottom side also dissipates heat. The heat is transfer in this case to the upper level as the upper side expedites the heat coming from the bottom.

An advantage of this process is life extenuation of the central processing unit. Management of the heat energy on a central processing unit lengthens the life of the working microprocessor. As heat management is kept under suitable working conditions all software and hardware components work in unison, further making it easier on the user.

Furthermore, another advantage of thoroughly dissipating heat from the microprocessor increases the mean time before failure on the CPU. This contemplates all components of a computer system by keeping a compatible working system. As the system functions at or close to engineering specification without any heat problems, connected peripheral work better in juncture.

### DETAILED DESCRIPTION OF THE PREFERRED EMBODIMENTS

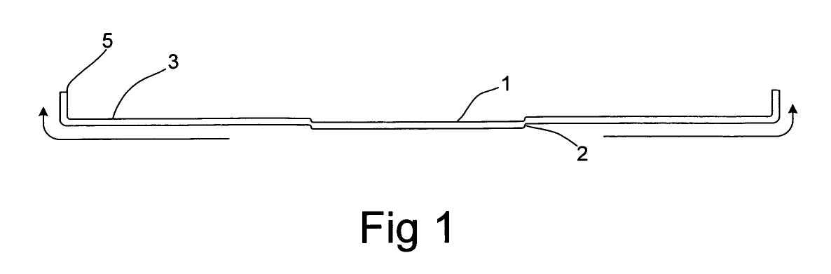

The bi-level thermal management heat sink is an invention that its innovative mechanism is a function of its design. An arrangement of having a thermal heat sink operating by two levels permit the extraction of excess heat at the bottom and upper part of a central processing unit. The term “microprocessor unit” as use herein is intended to be implicit as a broadest meaning of a but not limited to a microprocessor, a semiconductor device, a microchip, or central processing unit. The functions of said invention is incorporated by the integrations as in FIG. 1 by the chip concave 1, which permits a microchip to submerge into the lower plate. At the side of the chip concave 1 is a curvature 2 that snugly secures the microchip in place. At the surrounding sides is the base plate 3 that encompasses most of the lower plate. This area receives most of the heat emitted by the bottom part of a microprocessor unit. Heat emitted by the bottom side and the sides are then pass through the thermal arm 5 which in turns transfers the thermal energy to the upper plate heat sink.

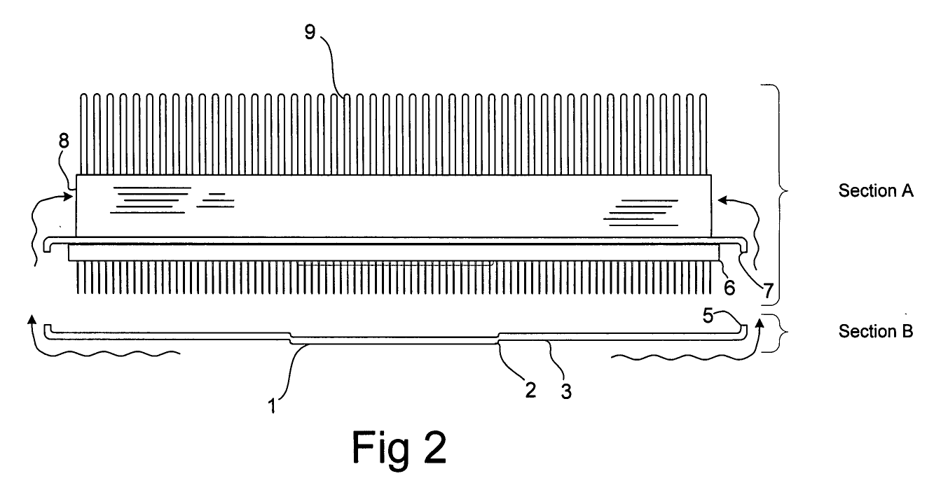

In FIG. 2 is the bottom heat plate, the chip concave 1 permit a microchip to submerge into the lower plate. At the side of the chip concave 1 is a curvature 2 that snugly secures the microchip in place. At the surrounding sides is the base plate 3 that encompasses most of the lower plate. This area receives most of the heat emitted by the bottom part of a microprocessor unit. Heat emitted by the bottom side and the sides are then pass through the thermal arm 5 which in turns transfers the thermal energy to the upper plate heat sink. FIG. 2 incorporates the upper heat plate that is sitting on top of a central processing unit 6. The closeness of the upper heat plate on top of the central processing unit herein incorporated in the FIG. 2 is for illustrative purposes of which is also an adaptable means of thermal transference. On top of the central processing unit 6 is the upper heat plate, which is incorporated by its sides by an upper thermal arm 7. The purpose of the upper thermal arm 7 is to induce and receive heat energy from the lower thermal arm 5. The upper thermal arm 7 is integrated to the heat sink base 8, which functions by its incorporation as receiver of heat energy emitted by the central processing unit 6. Integral arrangements of fins 9 are attach to the upper part of the heat sink base 8.

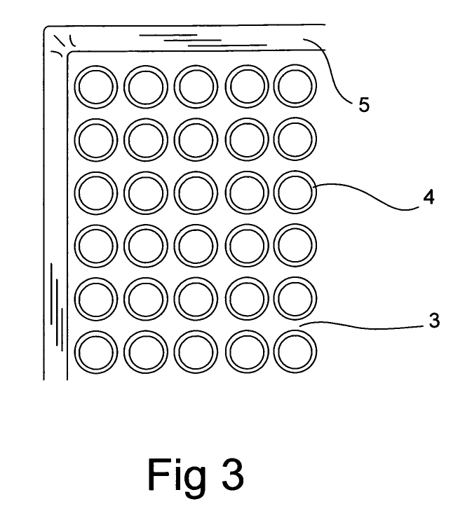

In FIG. 3 a sectional top view of the bottom heat plate. Working from the inside out FIG. 3 illustrates the section that takes the brunt of the heat as the heat energy emitted is receive by the base plate 3. The base plate 3 has multiple holes incorporated herein for illustrative purposes, as understood the pin array of microprocessors are uniquely design. FIG. 3 illustrates a typical assignment of a pin socket array 4. The pin socket array in its arrangement contains an insulation that separates electrical conductivity between the base plate 3 and the micro processing unit 6 pins. The insulation herein can be manufacture of well-known material in the industry. At the edge, a top view of the low thermal arm 5 illustrates how it incorporates in a corner.

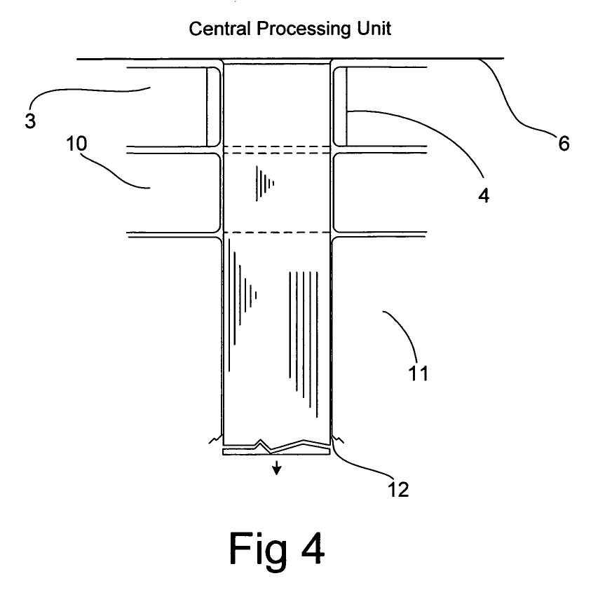

FIG. 4 is a side view illustration of pin inserted between the bottom heat plate. A central processing unit 6 that emits heat energy snugly sits on top of a heat plate. FIG. 4 shows how a central processing unit 6 incorporates with the invention. The base plate 3 permits a central processing unit 6 pin insertion between the base plate 3 that in turns has a pin socket array 4. Below lies a Zero Insertion Force socket cover clamp 10. The cover clamp 10 is the part of the Zero Insertion Force socket top part that is typical for securing central processing units 6. Below the Zero Insertion Force socket cover clamp 10 is the Zero Insertion Force socket base 11 that snugly can accept a pin 12 from the central processing unit 6.

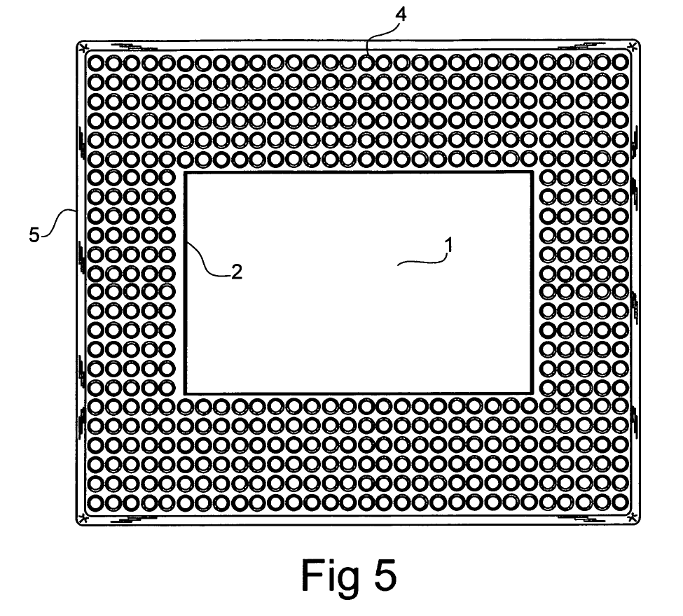

A top view of the bottom heat plate shown is FIG. 5. Working from the inside out, the illustration shows the part of the chip concave 1. The chip concave 1 is the center of the bottom heat plate. The chip concave 1 receives heat energy from the central processing unit 6, in addition to providing support. At the outer rims of the chip concave 1 is the curvature 2. The curvature 2 is the area of the bottom heat plate use for snugly fitting a microchip housing. Surrounding the curvature 2 is the insulating pin socket array 4 that resides within the base plate 3. At the outermost edge, the side of the bottom heat plate is the low thermal arm 5.

In conclusion the upper heat sink Section A and the base heat plate Section B work in unison to extract heat from an heat generating semiconductor device, in general a microprocessor.

### BRIEF DESCRIPTION OF THE PREFERRED EMBODIMENTS

FIG. 1 is a side view of the base heat plate Section B;

FIG. 2 is a view of a microprocessor in-between the upper heat sink Section A and base heat Section B;

FIG. 3 is a sectional top view of the base heat Section B;

FIG. 4 is a cross sectional view of a microprocessor pin between the base heat Section B and the Zero Inline Force Socket;

FIG. 5 is a top view of the base heat Section B.

What is claimed is:

1. Thermal heat transfer device for the proper removing of heat energy from a semiconductor device. A bi-level design is use to remove thermal energy from said semiconductor device. The double layer design made of a lower Section B and upper Section A makes said invention receive heat generated by semiconductor device. Said invention is able to transmit excess heat energy transferring it throughout its heat conducting metallic structure. By assistance of fanning the excess heat of said semiconductor device excess heat is expel.

2. A thermal heat transfer device according to claim 1, wherein said semiconductor device generally, a central processing unit produces heat when operational.

3. A thermal heat transfer device according to claim 1, wherein lower section B acts as a heat receiver from the semiconductor.

4. A thermal heat transfer device according to claim 1, wherein upper section A acts as a heat receiver from the semiconductor.

5. A thermal heat transfer device according to claim 1, wherein lower section B acts as a heat transmitter from semiconductor device to upper section A.

6. A thermal heat transfer device according to claim 1, wherein lower Section B and upper Section A act combine to retransmit heat.

7. A thermal heat transfer device according to claim 1, wherein lower Section B and upper Section A, accord by fanning expel heat.
